(19) United States
(12) Patent Application Publication
(10) Pub. No.: US 2026/0194388 A1
(43) Pub. Date: Jul. 9, 2026

(54) SOLID-STATE DEVICE INCLUDING A HEAT SEGREGATED LAYER INCLUDING A THERMAL BARRIER, AND METHOD OF FORMING THE SAME

(71) Applicant: PsiQuantum, Corp., Palo Alto, CA (US)

(72) Inventor: Matthew WINGERT, Orcas, WA (US)

(21) Appl. No.: 19/131,854

(22) PCT Filed: Nov. 16, 2023
(86) PCT No.: PCT/US2023/080045

§ 371 Date: May 21, 2025

Related U.S. Application Data
(60) Provisional application No. 63/384,751, filed on Nov. 22, 2022.

(51) Int. Cl. G01J 1/02; G01J 1/44; H10N 60/84; H10W 40/20; H10W 40/25

(52) U.S. Cl. CPC G01J 1/0252; G01J 1/44; H10N 60/84; H10W 40/233; G01J 2001/442; H10W 40/258

(57) ABSTRACT

A solid-state device includes a lower thermal contact, an upper thermal contact, an electronic device that generates heat located between the lower thermal contact and upper thermal contact; and a heat segregated layer embedding a low temperature device located between the lower thermal contact and the electronic device and including a thermal barrier for segregating the heat generated by the electronic device from the low temperature device.

### FIELD

The present disclosure relates to a solid-state device including a heat segregated layer including a thermal barrier, and method of forming the same.

### BACKGROUND

Currently, thermal through silicon vias (TSVs) may be used to increase thermal conductance through a thermally insulating substrate to which an active solid-state device (e.g., semiconductor chip, semiconductor die, photonic chip, photonic die, hybrid electro-optical die or chip, etc.) is attached. At room temperature, TSVs could be used to increase the amount of thermally conductive material within a substrate.

However, thermal interface resistances at cryogenic temperatures would negate the benefits. Presently, in-die thermal control technology may include one of two designs: in-die thermoelectric cooling or in-die microfluidic channels. However, both of these designs may be difficult to build and integrate within a solid-state device. In addition, these designs may not be functional at cryogenic temperatures (e.g., less than about 10-20 K, such as 4K or less).

### SUMMARY

According to an aspect of the present disclosure, a solid-state device includes a lower thermal contact, an upper thermal contact, an electronic device that generates heat located between the lower thermal contact and upper thermal contact; and a heat segregated layer embedding a low temperature device located between the lower thermal contact and the electronic device and including a thermal barrier for segregating the heat generated by the electronic device from the low temperature device.

According to another aspect of the present disclosure, a solid-state device includes a low temperature device located over a first side of a semiconductor layer, a metal or metal alloy heat shield at least partially surrounding the low temperature device, a metal or metal alloy heat sink located over a second side of the semiconductor layer opposite to the first side of the semiconductor layer, and a metallic connection between the heat shield and the heat sink.

According to another aspect of the present disclosure, a method of forming a solid-state device includes forming a low temperature device over a first side of a semiconductor layer; forming a metal or metal alloy heat shield at least partially surrounding the low temperature device; and forming a metallic connection between the heat shield and a metal or metal alloy heat sink located over a second side of the semiconductor layer opposite to the first side of the semiconductor layer.

### BRIEF DESCRIPTION OF THE DRAWINGS

For a better understanding of the various described embodiments, reference should be made to the Detailed Description below, in conjunction with the following drawings in which like reference numerals refer to corresponding parts throughout the Figures.

FIG. 1A is a vertical cross-sectional view of the solid-state device according to one or more embodiments.

FIG. 1B is another vertical cross-sectional view of the solid-state device according to one or more embodiments.

FIG. 2 is a flow chart illustrating a method of forming the solid-state device according to one or more embodiments.

FIG. 3 is a vertical cross-sectional view of the solid-state device, according to one or more embodiments.

FIG. 4 is a vertical cross-sectional view of the solid-state device having a first alternative design, according to one or more embodiments.

FIG. 5 is a vertical cross-sectional view of the solid-state device having a second alternative design, according to one or more embodiments.

FIG. 6 is a plan view (top-down view) of the solid-state device having a third alternative design, according to one or more embodiments.

FIG. 7 is a plan view (top-down view) of the solid-state device having a fourth alternative design, according to one or more embodiments.

### DETAILED DESCRIPTION

As discussed above, the embodiments of the present disclosure are directed a solid-state device including a heat segregated layer including a thermal barrier, and method of forming the same, the various aspects of which are discussed herein in detail. The drawings are not necessarily drawn to scale. Multiple instances of an element may be duplicated where a single instance of the element is illustrated, unless absence of duplication of elements is expressly described or clearly indicated otherwise. Ordinals such as “first,” “second,” and “third” are employed merely to identify similar elements, and different ordinals may be employed across the specification and the claims of the instant disclosure. The same reference numerals refer to the same element or similar element. Unless otherwise indicated, elements having the same reference numerals are presumed to have the same composition. As used herein, a first element located “on” a second element can be located on the exterior side of a surface of the second element or on the interior side of the second element. As used herein, a first element is located “directly on” a second element if there exist a physical contact between a surface of the first element and a surface of the second element. As used herein, a “layer” refers to a continuous portion of at least one material including a region having a thickness. A layer may consist of a single material portion having a homogeneous composition, or may include multiple material portions having different compositions.

As used herein, a “conductive material” refers to a material having electrical conductivity greater than 1.0×10⁵ S/cm. As used herein, an “insulator material” or a “dielectric material” refers to a material having electrical conductivity less than 1.0×10⁻⁵ S/cm. As used herein, a “semiconducting material” refers to a material having electrical conductivity in the range from 1.0×10⁻⁵ S/cm to 1.0−10⁵ S/cm. As used herein, a “metallic material” refers to a conductive material including at least one metallic element therein. All measurements for electrical conductivities are made at the standard condition.

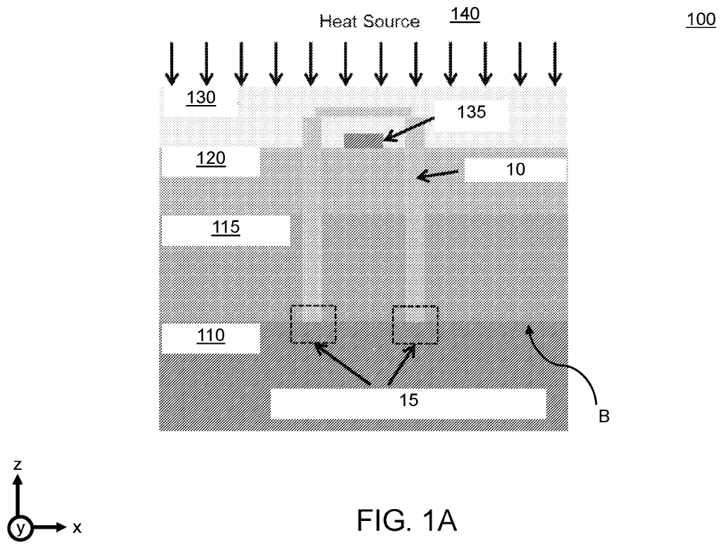

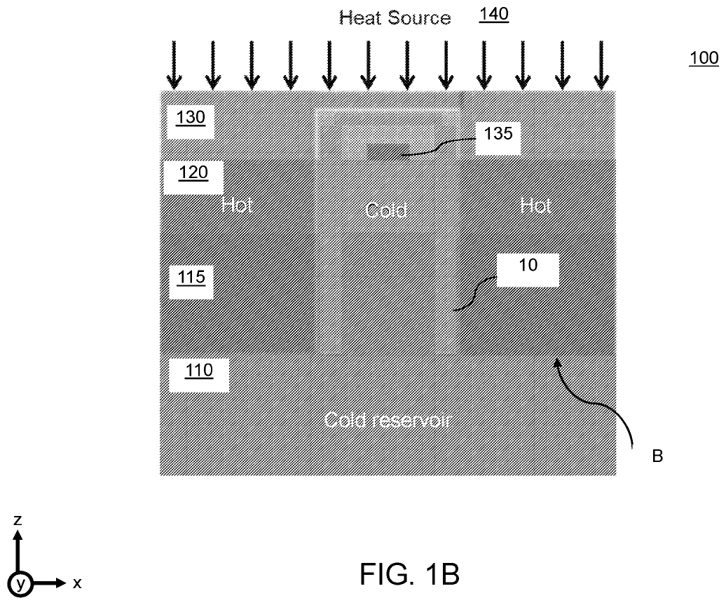

FIG. 1A is a vertical cross-sectional view of the solid-state device 100 according to one or more embodiments. The solid-state device 100 may help to ensure that highly localized volumes (micro-scale or possibly even larger) containing one or more components and/or devices (e.g., electrical device, photonic device, etc.) may be cooled to a lower temperature than the surrounding die material. In one embodiment, the solid-state device 100 may comprise an electronic die (e.g., semiconductor die), a photonic die, or a hybrid electronic-photonic die.

As illustrated in FIG. 1A, the solid-state device 100 may include a heat sink 110 (e.g., metal heat sink, such as a copper plate), a semiconductor layer 115 (e.g., silicon layer) on the heat sink 110, a lower dielectric layer 120 (e.g., heat segregated layer) on the semiconductor layer 115, and a device layer 130 on the lower dielectric layer 120. The device layer 130 may comprise a dielectric material layer (e.g., silicon oxide layer) embedding a low temperature device 135. The low temperature device 135 may be any device that operates at a lower temperature than other areas of the solid-state device 100 (e.g., solid-state die).

In one embodiment, the solid-state device is a hybrid electronic and photonic solid-state device. The photonic portion of the device may include a photonic integrated circuit containing the device layer 130 and the low temperature device 135. For example, the photonic integrated circuit may include one or more interferometers optically connected to one or more waveguides, and one or more low temperature superconducting wires located adjacent to one or more waveguides. The interferometers act as optical switches, while the superconducting wires are located in a detector, and detect a passage of a photon through the adjacent waveguide. Specifically, the photon raises the temperature of the superconducting wire above its critical temperature, thus temporarily increasing the resistivity of the superconducting wire. The increase in resistivity may be detected by passing a current through the superconducting wire using the electronic portion of the device (e.g., semiconductor transistors and/or other electronic control and detection circuitry).

Thus, in one embodiment, the low temperature device 135 may comprise a superconducting wire and/or an interferometer which is operated at low temperatures (e.g., cryogenic temperatures below 120 K, at a temperature of 4 K, at a temperature of 2 K). The electronic portion of the device may comprise an electronic integrated circuit which generates heat during operation and is labeled “heat source” 140 in FIG. 1A. In some example embodiments, the heat sink 110 may be in thermal contact with a cryostat, such as a liquid helium cryostat, which is maintained at a temperature of 4 K or less. The heat shield 10 can provide scatter mitigation to keep scattered light from reaching the low temperature device (e.g., optical shielding for a superconducting photon detector) and further provide thermal functionality as discussed below.

As further illustrated in FIG. 1A, the solid-state device 100 may include a heat shield 10 (e.g., a metal heat shield). The heat shield 10 may include copper, copper alloy, and/or other suitable metals or alloys. The heat shield 10 may extend from the device layer 130 to the heat sink 110. The heat shield 10 may be formed on opposing sides of the low temperature device 135 in the device layer 130. In at least one embodiment, the heat shield 10 may substantially surround the low temperature device 135 in the x-y plane. The heat shield 10 may also be formed over the low temperature device 135. In at least one embodiment, the heat shield 10 may substantially surround the top and sides of the low temperature device 135. The heat shield 10 may contact the heat sink 110 so as to form a connection 15 (e.g., thermal connection, denoted by dashed squares in FIG. 1A) with the heat sink 110 (e.g., fully metallic thermal connection).

As further illustrated in FIG. 1A, the heat source 140 may generate heat that is transmitted to the device layer 130. In one embodiment, the heat source 140 may comprise electronic devices, such as transistors, etc. The heat shield 10 may serve as a thermal barrier that impedes the transmission of heat from the heat source 140 to the region of the solid-state device inside the heat shield 10.

The heat shield 10 may include, for example, a wall structure having a vertical metal shield/shell fully or partially enclosing a small sub-volume within the solid-state device 100. A top of the wall structure (e.g., the portion over the low temperature device 135) may include a metal plane or multiple layers (e.g., metal layers) which make metallic contact (e.g., full metal contact) with the top of the sidewalls of the heat shield 10.

A method of forming the solid-state device 100 includes forming the layers 120 and 130, the low temperature device 135 and the heat shield over the semiconductor layer 115, which may comprise a silicon substrate. A bottom surface of the semiconductor layer 115 may then be thinned over the whole solid-state device 100 or just locally underneath the heat shield 10, such that the bottom ends of the heat shield 10 are exposed. The exposed heat shield 10 (e.g., metal contacts) and the rest of the surface of the backside B of the semiconductor layer 115 may then be bonded to the heat sink 10 (e.g., metallic heat sink or heat sink that contains metallic thermal contacts) such that a fully metallic contact may be created from the heat sink 110 and throughout the heat shield 10 (e.g., metallic shield, top of wall structure, etc.) within the solid-state device 100. The connection 15 may include one or multiple metallic layers, such as metal or metal alloy bonding layers (e.g., films) that are deposited to bond the heat shield 10 to the heat sink 110. The solid-state device 100 may therefore utilize the low thermal interface resistance between metals in comparison to the higher thermal interface resistance between metals and dielectrics or semiconductors to provide a selective heat transfer pathway from the heat sink 110 into the layers of the solid-state device 100 through the heat shield 10 (e.g., metal shield structure).

FIG. 1B is another vertical cross-sectional view of the solid-state device 100 during operation according to one or more embodiments. In particular, FIG. 1B illustrates a segregation of heat (e.g., thermal regions) resulting from heat transmitted to the solid-state device 100 from the heat source 140. As illustrated in FIG. 1B, a portion of the lower dielectric layer 120, a portion of the device layer 130 and the low temperature device 135 are located in a cold region inside the heat shield 10. In contrast, other portions of the lower dielectric layer 120 and the device layer 130 located outside of the heat shield 10 comprise hot regions. Thus, the low temperature device 135 may be located in a colder region of the solid-state device 100 than other components of the solid-state device 100. Further, the heat sink 110 may constitute a cold reservoir for dissipating the heat from the heat source 140.

In particular, the heat shield 10 (e.g., in-die heat shield structure) may thermalize to the heat sink 110 more than to the surrounding die material (e.g., semiconductor layer 115, lower dielectric layer 120, etc.) due to the lower metallic thermal resistance between the heat shield 10 and heat sink 110 than the thermal resistance between the heat shield 10 and surrounding die dielectric and semiconductor layers. The enclosed top and sealed bottom of the heat shield 10 may also increase the optical isolation of the volume in case the enclosed device(s) are optically sensitive. In this way, the temperature within the heat shield (the “cold” region) is more uniform and stabilized, and further the region within the heat shield 10 as in FIG. 1B can achieve colder temperatures.

In an alternative embodiment, the solid-state device 100 may be inverted. The solid-state device 100 may, therefore, be cooled through a heat shield (metal structure) that extends to the top surface of the solid-state device 100 and is attached to another heat sink 110. Alternatively, instead of thinning the semiconductor layer (e.g., silicon substrate) 115 over the entire solid-state device 100 to expose the heat shield 10, blind holes may be ‘drilled’ (e.g., by laser drilling, etching, or other methods) through the semiconductor layer (e.g., silicon wafer) 115 just under the enclosed low temperature device 135 to expose the metal of the heat shield 10, and then filled in with deposited metal (e.g., copper or copper alloy) to form the all-metallic thermal pathway. Alternatively or additionally, one or more deposited metal films may be used as intermediary adhesion and/or oxidation protection layer between the exposed heat shield 10 and the heat sink 110. Alternatively or additionally, additional interface films may be placed between the heat shield 10 and the lower dielectric layer 120 and semiconductor layer 115 to tune the thermal interface resistance to either increase or decrease the temperature difference between the inner cold volume and the outer hot material. Alternatively or additionally, multiple surrounding heat shields 10 can be used to add thermal isolation of the inner cold volume. The various shells could also have different interfacing films such that inner shields are well thermally connected to the surroundings and the outer shields are less thermally connected which would allow the inner volume to better thermalize to the temperature of the cold reservoir. Alternatively, a top-side thermal bath may be at a higher temperature to keep the enclosed component or components at an elevated temperature in comparison to the rest of the solid-state device 100.

The solid-state device 100 may provide several advantages over typical designs. In particular, the solid-state device 100 may allow for highly localized in-die cooling to temperature sensitive components 135 which are currently not achievable at cryogenic temperature.

The solid-state device 100 may also include several different applications. The applications may include, for example, cryogenic applications, cryogenic electronics/photonics, quantum computing, and localized device thermal control. In particular, photonic or hybrid dies containing an in-die heat shield may be attached to a cold plate in order to facilitate heat dissipation and keep specific components (e.g., device 135) at a colder temperature than the surrounding die areas.

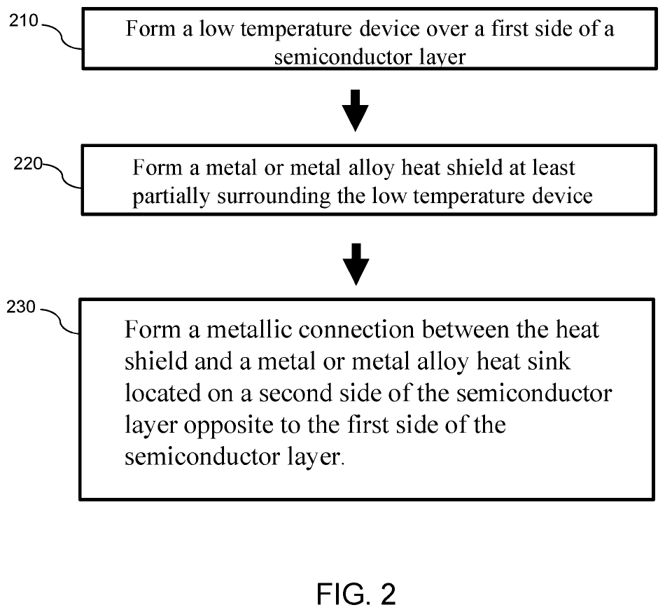

FIG. 2 is a flow chart illustrating a method of forming the solid-state device 100 according to one or more embodiments. Step 210 may include forming a low temperature device 135 over a first side of a semiconductor layer 115. Step 220 may include forming a metal or metal alloy heat shield 10 at least partially surrounding the low temperature device 135. Step 230 may include forming a metallic connection 15 between the heat shield 10 and a metal or metal alloy heat sink 110 located on a second side of the semiconductor layer 115 opposite to the first side of the semiconductor layer 115. The metallic connection 15 is a direct physical connection between one metal or metal alloy and another metal or metal alloy.

In one embodiment, the connection 15 may be formed by thinning the semiconductor layer 115 to expose the bottom of the heat shield 10 on the second (e.g. bottom) side of the semiconductor layer 115 and forming the heat sink 110 on the second (e.g., bottom) side of the semiconductor layer 115 and in contact with the bottom of the heat shield 10 exposed on the second (e.g. bottom) side of the semiconductor layer 115.

In another embodiment, the connection 15 may be formed by forming openings through the semiconductor layer 115 to expose the bottom of the heat shield 10, filling the openings with metal or metal alloy vias which contact the bottom of the heat shield 10, and forming the heat sink 110 on the second (e.g., bottom) side of the semiconductor layer 115 and in contact with the vias.

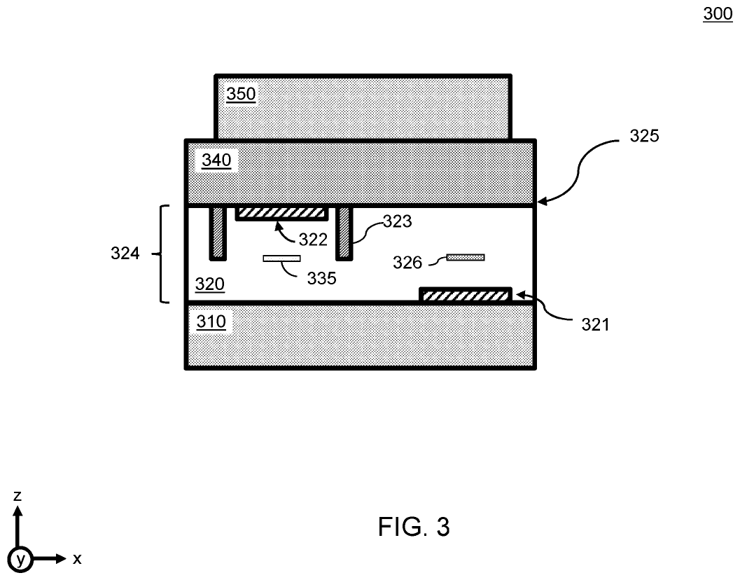

FIG. 3 is a vertical cross-sectional view of the solid-state device 300, according to one or more embodiments. As illustrated in FIG. 3, the solid-state device 300 may include one or more thermal barriers 321, 322 (e.g., cryogenic local thermal barriers) for on-die segregation of heat (e.g., heat and temperature).

In typical devices, it may be difficult to keep separate temperature profiles on a die in a cryogenic environment (e.g., hot electronics, cold superconductors, local hot spots for other devices, etc.). The typical devices may cool the entire die, provide undercut trenches for heaters and/or provide thermoelectric local hot-spot coolers. A limitation of these devices is that heat transfer may be difficult to control compared to other transport phenomena. In addition, maintaining large temperature differences over small physical areas may be even more difficult.

In contrast to typical devices, the solid-state device 300 may include one or more thermal barriers 321, 322 that may be locally formed to segregate temperature and heat flux on a die. The solid-state device 300 may, therefore, include two pathways for heat removal. These pathways may allow certain areas to exist at different operate temperatures.

As illustrated in FIG. 3, the solid-state device 300 may include a bottom thermal contact 310. The bottom thermal contact 310 may include, for example, the semiconductor layer 115, such as a silicon layer, and optionally the metal or metal alloy heat sink 110 located below the semiconductor layer 115, as described above with regard to FIG. 1A.

The solid-state device 300 may also include a dielectric layer (heat segregated layer) on the bottom thermal contact 310. The dielectric layer 320 may include, for example, silicon dioxide. In one embodiment, the dielectric layer 320 may include two or more sublayers, such as the lower dielectric layer 120 and the device layer 130 as described above with regard to FIG. 1A. The dielectric layer 320 may embed a low temperature device 335. The low temperature device 335 may comprise the same device as the low temperature device 135 described above with regard to FIG. 1A. For example, the low temperature device 335 may comprise a low temperature superconducting wire, such as a niobium wire. In one embodiment, the combination of the dielectric layer 320 and the low temperature device 335 may comprise a photonic integrated circuit 324.

The dielectric layer 320 may include one or more thermal barriers 321, 322. The addition of the local thermal barriers 321, 322 can may allow the solid-state device 300 to tolerate much higher heat loads in an electronics die for the same temperature.

In particular, a lower local cross-plane thermal barrier 321 may be formed in a lower portion of the dielectric layer 320 on the bottom thermal contact 310. The lower local cross-plane thermal barrier 321 may impede heat flux dissipation from above to create a local hot spot 326. An upper local cross-plane thermal barrier 322 may also be formed in an upper portion of the dielectric layer 320 over the low temperature device 335. The upper local cross-plane thermal barrier 322 may redirect the heat flux from the heat source (such as the electronics integrated circuit 340) upwards in the z-direction to create a local cold spot at the location of the low temperature device 335 underneath the upper local cross-plane thermal barrier 322.

One or more through vias 323 may also be formed in the upper portion of the dielectric layer 320 near the upper local cross-plane thermal barrier 322 (e.g., on opposing sides of the upper local cross-plane thermal barrier 322 in the x-direction) on opposite sides of the low temperature device 335. As illustrated in FIG. 3, the cold spot may be formed at the location of the low temperature device 335 under the upper local cross-plane thermal barrier 322 and between the through vias 323, and the hot spot 326 may be formed over the lower local cross-plane thermal barrier 322 on the opposite side of one of the through vias 323.

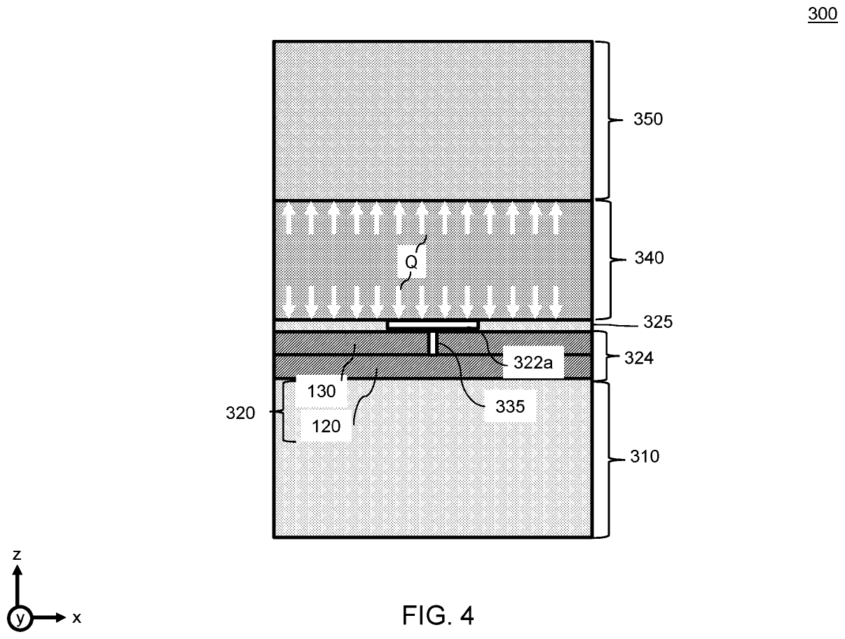

In one embodiment, the lower local cross-plane thermal barrier 321, the upper local cross-plane thermal barrier 322 and/or the through vias 323 may comprise a metal or metal alloy, such as copper or copper alloy. In an alternative embodiment, the lower local cross-plane thermal barrier 321, the upper local cross-plane thermal barrier 322 and/or the through vias 323 may comprise voids (also referred to as air gaps), as will be described in more details below with regard to FIG. 4.

The solid-state device 300 may also include an electronics integrated circuit 340 that may include one or more electrical devices (e.g., semiconductor transistors, etc.). The electrical devices may be formed, example, on a semiconductor (e.g., silicon) substrate. The electrical devices may be formed (e.g., embedded), for example, in a dielectric material of the electronics integrated circuit 340. The electrical devices may constitute a heat load (i.e., the heat source 140 described above) in the solid-state device 300. The electronics integrated circuit 340 may be bonded to the dielectric layer 320, for example, by a bond 325, which may comprise a metal to metal bond, a dielectric to dielectric bond and/or a hybrid fusion bond.

The solid-state device 300 may also include an upper thermal contact 350. The upper thermal contact 350 may have a higher base temperature than the bottom thermal contact 310. In at least one embodiment, a temperature of the upper thermal contact 350 may be at least 4.2K while a temperature of the bottom thermal contact 310 may be less than 4.2K, such as about 2.2K. In extreme cases, the upper thermal contact 350 can be kept at 77K (e.g., liquid nitrogen temperature) or even higher, while the bottom thermal contact 310 can be kept at less than 4.2K, such as 2.2K. The upper thermal contact 350 may include, for example, a metal plate or block, such as a copper, copper alloy, etc., plate or block.

FIG. 4 is a vertical cross-sectional view of the solid-state device 300 having a first alternative design, according to one or more embodiments. As illustrated in FIG. 4, in the first alternative design, the solid-state device 300 may include the bottom thermal contact 310. The bottom thermal contact 310 may include a silicon layer (e.g., layer 115 described above).

The solid-state device 300 may also include the photonic integrated circuit 324 including the dielectric layer 320 and the low temperature device 335. The dielectric layer 320 may include the above described lower dielectric layer 120 and the device layer 130 embedding the low temperature device 335.

The solid-state device 300 may also include the electronics integrated circuit 340 and the upper thermal contact 350 as described above. The solid-state device 300 may additionally include the bond 325, which in this embodiment may comprise one or more metal bonding layers (e.g., copper or copper layer layers) between the electronics integrated circuit 340 and the photonic integrated circuit 324. The bond (e.g., bonding metal layer(s) 325 include the upper thermal barrier 322A that in this embodiment may include a void, such as an unfilled trench. The upper thermal barrier 322A is located above the low temperature device 335.

In at least one embodiment, the solid-state device 300 may include R values (e.g., thermal insulation values) of R_{SiO2—Si} between the lower thermal contact 310 (e.g., silicon) and the dielectric layer 320 (e.g., silicon oxide), R_{SiO2—Cu} between the dielectric layer 320 (e.g. silicon oxide) and the bond 325 (e.g., copper bonding layer), R_{Si—Cu} between the bond (e.g., copper bonding layer) 325 and the electronics integrated circuit (e.g., silicon substrate of the circuit) 340, and R_{Cu—In—Si} between the electronics integrated circuit 340 (e.g., silicon substrate) and the upper thermal contact 350 (e.g., copper plate or block with optional indium bonding layer).

Addition of the thermal barrier 322A may reduce the temperature of the low temperature device by at least 50%, such as between 60% and 260%.

Thermal barriers that comprise voids (e.g., local voids, local unfilled trenches, and/or unfilled vias), can be fabricated in multiple ways. In one embodiment, such thermal barriers may be formed by bonding an electronics die containing the electronic integrated circuit to an etched-out structure containing a trench (e.g., a photonics die containing an etched out trench and/or a trench located in the bonding layer(s) between the electronics and photonics die). The unfilled vias may be formed by pinching off vias by non-conformally depositing a dielectric layer (e.g., silicon oxide) on top of the via openings without filling the vias. Voids may also be formed by isotropically etching out a dielectric layer, such as silicon oxide or by etching out a trench in the electronics die prior to bonding the electronics die to the photonics die.

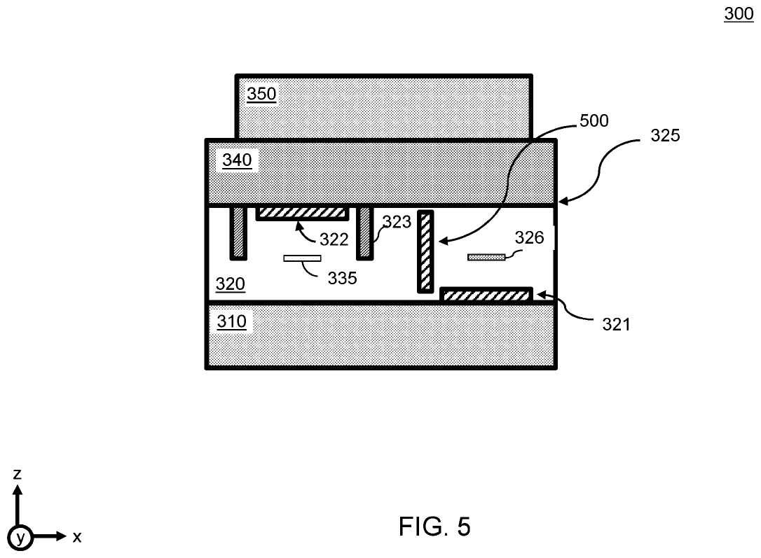

FIG. 5 is a vertical cross-sectional view of the solid-state device 300 having a second alternative design, according to one or more embodiments. As illustrated in FIG. 5, the second alternative design may include an additional in-plane vertical thermal barrier 500 between the low temperature device 335 and the hot spot 326. The in-plane thermal barrier 500 may further thermally segregate the cold spot at the low temperature device 335 from the hot spot 326. Thus, the second alternative design may utilize a combination of cross-plane and in-plane thermal barriers and through vias to segregate hot-spots and cold-spots.

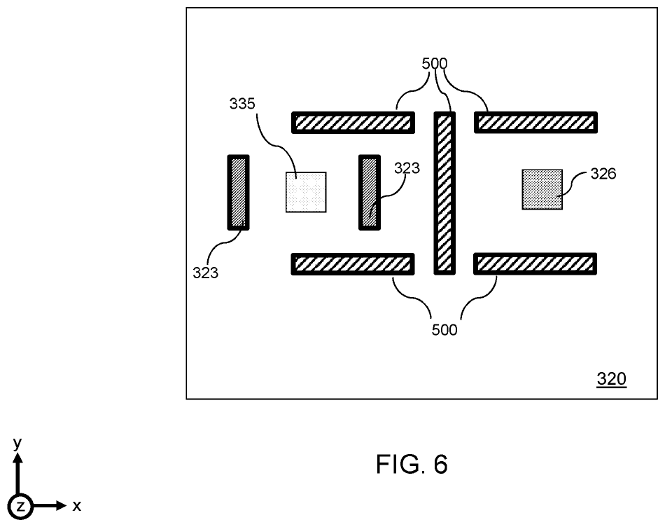

FIG. 6 is a plan view (top-down view) of the solid-state device 300 having a third alternative design, according to one or more embodiments. The upper thermal contact 350 and electronics integrated circuit 340 have been omitted in FIG. 6 for ease of explanation. As illustrated in FIG. 6, the third alternative design may include a plurality of in-plane thermal barriers 500 extending in the x-direction and/or in the y-direction to segregate the hot-spot 326 and cold-spot at the low temperature device 335.

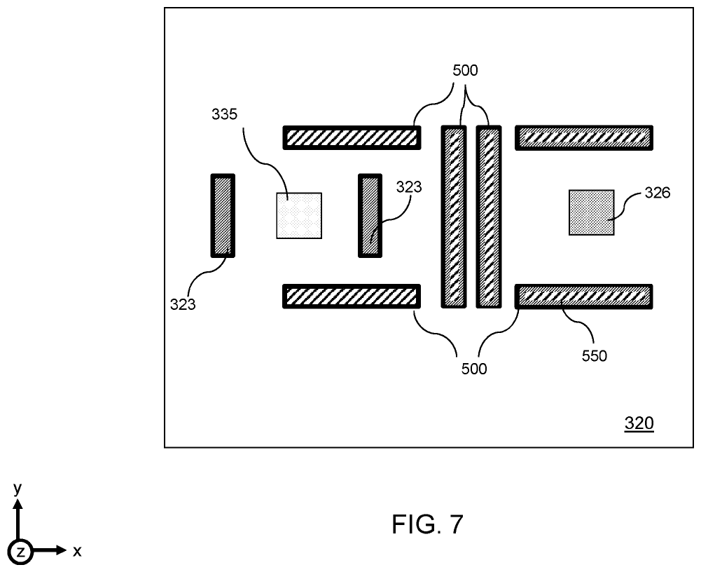

FIG. 7 is a plan view (top-down view) of the solid-state device 300 having a fourth alternative design, according to one or more embodiments. The upper thermal contact 350 and electronics integrated circuit 340 have been omitted in FIG. 6 for ease of explanation. As illustrated in FIG. 6, in the fourth alternative design one or more of the in-plane thermal barriers 500 may include in-plane lined thermal barriers to reduce thermal radiation exchange between the hot spot 322b and cold spot 322a. That is, the in-plane thermal barriers 500 may include a surface liner layer 550 which absorbs or reflects thermal radiation (i.e., infrared radiation).

In some embodiments, etched out (i.e., unfilled, hollow) vias can further isolate cold or hot spots. The unfilled vias and trenches can be used as in-plane thermal barriers to impede heat flow to and/or from nearby structures operating at different temperatures. Combinations of cross-plane and in-plane thermal barriers can be used to segregate components allowing them to operate at different temperatures and thermally sink to different heat baths. Other thermal barriers include multiple alternating materials such as silicon nitride/silicon oxide. Multiple thermal barriers can be fabricated in series to increase thermal isolation or in parallel to segregate larger areas. Thin lining materials deposited on the inside surface of barriers can be used to modify (e.g., increase or decrease) infrared surface emissivity to reduce thermal radiation heat transfer through barriers.

The solid-state device of the embodiments of the present disclosure may allow localized cooling in small in-die volumes. The solid-state device may also allow for temperature sensitive components to be closer to heat sources as the enclosed and/or thermal barrier separated components will be cooler than the in-die lateral temperature gradient around them.

In particular, the solid-state device may ensuring that the temperature sensitive components that must be cold can stay cold even while the surrounding environment is warmer (e.g., hotter) than a useful operating temperature of the temperature sensitive components, particularly when there is a high density of power dissipating components or just a high-power density within the die. The heat shield or thermal barrier may also shield the bottom of the enclosed component from light incident from the backside of the solid-state device in the case of light sensitive components in the photonic integrated circuit.

The following are example embodiments:
Example 1: A solid-state device, comprising: a lower thermal contact; an upper thermal contact; an electronic device that generates heat located between the lower thermal contact and upper thermal contact; and a heat segregated layer embedding a low temperature device located between the lower thermal contact and the electronic device and including a thermal barrier for segregating the heat generated by the electronic device from the low temperature device
Example 2: The solid-state device as example 1 describes, wherein the heat segregated layer comprises a photonic integrated circuit having an operating temperature that is less than an operating temperature of the electronic device.
Example 3: The solid-state device as either of examples 1 or 2 describe, wherein the low temperature device comprises a superconducting wire.
Example 4: The solid-state device as any of examples 1-3 describe, wherein the electronic device comprises an electronic integrated circuit.
Example 5: The solid-state device as any of examples 1-4 describe, wherein the thermal barrier comprises a void between the photonic integrated circuit and the electronic integrated circuit.
Example 6: The solid-state device as any of examples 1-5 describe, wherein: the lower thermal contact comprises a metal heat sink; and the thermal barrier comprises a metal heat shield which at least partially surrounds the low temperature device.
Example 7: The solid-state device as any of examples 1-6 describe, wherein the metal heat sink comprises a metal alloy heat sink; and wherein the metal heat shield comprises a metal alloy heat shield.
Example 8: The solid-state device as any of examples 1-7 describe, further comprising a fully metallic thermal connection between the metal heat sink and the metal heat shield.
Example 9: The solid-state device as any of examples 1-8 describe, wherein the metal heat sink directly physically contacts the metal heat shield to provide the fully metallic thermal connection between the metal heat sink and the metal heat shield.
Example 10: The solid-state device as any of examples 1-9 describe, wherein the thermal barrier comprises an upper cross-plane thermal barrier located on an upper surface of the heat segregated layer over the low temperature device, and contacting the electronic device.
Example 11: The solid-state device as any of examples 1-10 describe, wherein the heat segregated layer further comprises a plurality of through vias on opposing lateral sides of the upper cross-plane thermal barrier.
Example 12: The solid-state device as any of examples 1-11 describe, wherein the thermal barrier further comprises a lower cross-plane thermal barrier located on a bottom surface of the heat segregated layer and contacting the lower thermal contact.
Example 13: The solid-state device as any of examples 1-12 describe, wherein the thermal barrier segregates heat in the heat segregated layer such that the heat segregated layer comprises a cold region containing the low temperature device located under the upper cross-plane thermal barrier and a hot region located over the lower cross-plane thermal barrier.
Example 14: The solid-state device as any of examples 1-13 describe, wherein the thermal barrier further comprises an in-plane thermal barrier between the upper cross-plane thermal barrier and the lower cross-plane thermal barrier.
Example 15: The solid-state device as any of examples 1-14 describe, wherein the in-plane thermal barrier is substantially perpendicular to the upper cross-plane thermal barrier and the lower cross-plane thermal barrier.
Example 16: The solid-state device as any of examples 1-15 describe, wherein the thermal barrier comprises a metal.

Example 17: The solid-state device as any of examples 1-16 describe, wherein the thermal barrier comprises a void.
Example 18: The solid-state device as any of examples 1-17 describe, wherein the low temperature device comprises a photon detector.
Example 19: A solid-state device, comprising: a low temperature device located over a first side of a semiconductor layer; a metal heat shield at least partially surrounding the low temperature device; a metal heat sink located over a second side of the semiconductor layer opposite to the first side of the semiconductor layer; and a metallic connection between the metal heat shield and the metal heat sink.
Example 20: A method of forming a solid-state device, comprising: forming a low temperature device over a first side of a semiconductor layer; forming a metal heat shield at least partially surrounding the low temperature device; and forming a metallic connection between the metal heat shield and a metal heat sink located over a second side of the semiconductor layer opposite to the first side of the semiconductor layer.

The preceding description of the disclosed embodiments is provided to enable any person skilled in the art to make or use the present invention. Various modifications to these embodiments will be readily apparent to those skilled in the art, and the generic principles defined herein may be applied to other embodiments without departing from the spirit or scope of the invention. Thus, the present invention is not intended to be limited to the embodiments shown herein but is to be accorded the widest scope consistent with the following claims and the principles and novel features disclosed herein.

1. A solid-state device, comprising:
a lower thermal contact;
an upper thermal contact;
an electronic device that generates heat located between the lower thermal contact and upper thermal contact; and
a heat segregated layer embedding a low temperature device located between the lower thermal contact and the electronic device and including a thermal barrier for segregating the heat generated by the electronic device from the low temperature device.

2. The solid-state device of claim 1, wherein the heat segregated layer comprises a photonic integrated circuit having an operating temperature that is less than an operating temperature of the electronic device.

3. The solid-state device of claim 2, wherein the low temperature device comprises a superconducting wire.

4. The solid-state device of claim 2, wherein the electronic device comprises an electronic integrated circuit.

5. The solid-state device of claim 2, wherein:
the lower thermal contact comprises a metal heat sink; and
the thermal barrier comprises a metal heat shield which at least partially surrounds the low temperature device.

6. The solid-state device of claim 5, wherein the metal heat sink comprises a metal alloy heat sink; and wherein the metal heat shield comprises a metal alloy heat shield.

7. The solid-state device of claim 5, further comprising a fully metallic thermal connection between the metal heat sink and the metal heat shield.

8. The solid-state device of claim 7, wherein the metal heat sink directly physically contacts the metal heat shield to provide the fully metallic thermal connection between the metal heat sink and the metal heat shield.

9. The solid-state device of claim 4, wherein the thermal barrier comprises a void between the photonic integrated circuit and the electronic integrated circuit.

10. The solid-state device of claim 1, wherein the thermal barrier comprises an upper cross-plane thermal barrier located on an upper surface of the heat segregated layer over the low temperature device, and contacting the electronic device.

11. The solid-state device of claim 10, wherein the heat segregated layer further comprises a plurality of through vias on opposing lateral sides of the upper cross-plane thermal barrier.

12. The solid-state device of claim 10, wherein the thermal barrier further comprises a lower cross-plane thermal barrier located on a bottom surface of the heat segregated layer and contacting the lower thermal contact.

13. The solid-state device of claim 12, wherein the thermal barrier segregates heat in the heat segregated layer such that the heat segregated layer comprises a cold region containing the low temperature device located under the upper cross-plane thermal barrier and a hot region located over the lower cross-plane thermal barrier.

14. The solid-state device of claim 13, wherein the thermal barrier further comprises an in-plane thermal barrier between the upper cross-plane thermal barrier and the lower cross-plane thermal barrier.

15. The solid-state device of claim 14, wherein the in-plane thermal barrier is substantially perpendicular to the upper cross-plane thermal barrier and the lower cross-plane thermal barrier.

16. The solid-state device of claim 1, wherein the thermal barrier comprises a metal.

17. The solid-state device of claim 1, wherein the thermal barrier comprises a void.

18. A solid-state device, comprising:
a low temperature device located over a first side of a semiconductor layer;
a metal heat shield at least partially surrounding the low temperature device;
a metal heat sink located over a second side of the semiconductor layer opposite to the first side of the semiconductor layer; and
a metallic connection between the metal heat shield and the metal heat sink.

19. The solid-state device of claim 1, wherein the low temperature device comprises a photon detector.

20. A method of forming a solid-state device, comprising:
forming a low temperature device over a first side of a semiconductor layer;
forming a metal heat shield at least partially surrounding the low temperature device; and
forming a metallic connection between the metal heat shield and a metal heat sink located over a second side of the semiconductor layer opposite to the first side of the semiconductor layer.
